(19) United States
(12) Patent Application Publication
(10) Pub. No.: US 2001/0044919 A1
(43) Pub. Date: Nov. 22, 2001

(54) Method and apparatus for improved perormance sliding window decoding

(76) Inventors: Brian S. Edmonston, Poway, CA (US); Paul K. Gray, South Australia (AU)

Correspondence Address: Brian S. Edmonston, iCoding Technology, Inc., Suite 466, 11770 Bernardo Plaza Court, San Diego, CA, 92128, US

(21) Appl. No.: 09/849,656

(22) Filed: May 4, 2001

Related U.S. Application Data
(60) Provisional application No. 60/202,344, filed on May 5, 2000.

(51) Int. Cl. H03M 13/00

(52) U.S. Cl. 714/752

(57) ABSTRACT

A method and apparatus for improving the performance of decoder that uses a sliding window decoder is described. In accordance with one embodiment of the invention, receive samples are decoded by first processing continuously in a first direction and using overlapping windows in a second direction, and then by decoded continuously in the second direction and using overlapping windows in the first direction. Typically, the decoding steps correspond to subiterations in a decoding iteration of a turbo code or other iterative code. The entire decoding process typically involves multiple decoding iterations and therefore has particular application to turbo codes and as well as other codes designed for iterative decoding.

### CROSS-REFERENCE TO RELATED APPLICATIONS

This application claims priority to U.S. Patent Application Serial No. 60/202,344, entitled “Method and Apparatus for Improved Performance Sliding Window Decoding”, filed on May 5, 2000 and assigned to the assignee of the present invention.

### FIELD OF THE INVENTION

The present invention relates to the area of communications and forward error correction. More particularly, the present invention relates to a method and apparatus for improved performance decoding with a sliding window decoder.

### BACKGROUND OF THE INVENTION

Turbo codes typically use a maximum a posteriori (MAP) soft-input-soft-output (SISO) decoder to provide substantially improved transmission performance over previously existing forward error correction techniques. A general description of parallel turbo code can be found in U.S. Pat. No. 5,446,747 entitled “Error-correction Coding Method With at Least Two Systematic Convolution Codings in Parallel, Corresponding Iterative Decoding Method, Decoding Module and Decoder,” filed Apr. 16, 1992 assigned to France Telecom and incorporated herein by reference.

The MAP decoder is sometimes implemented using a sliding window architecture that reduces memory requirements substantially over continuous and block decoding approaches. A first description of a sliding window MAP decoder is described in A Soft-input Soft-Output Maximum A Posteriori (MAP) Modulate to Decode Parallel and Serial Concatenated Codes, S Benedetto, D. Divsalar, G. Montorsi, and F. Pollara, NDA TDA Progress Report 42-127, Nov. 15, 1996. Another description of a sliding window decoder is described in An Intuitive Justification and a Simplified Implementation of the MAP Decoder for Convolutional Codes, Andrew J. Viterbi, IEEE Journal on Selected Area in Communications, Vol. 16, No 2, February 1998.

Without the use of a sliding window architecture, practical implementation of MAP decoders on an integrated circuit is severely limited. Thus, sliding window decoder are highly useful. The use of a sliding window MAP decoder, however, causes some degradation in the decoding performance, and of the associated turbo decoder relative to a turbo decoder implemented using a “continuous” MAP decoder.

The present invention increases the number of practical uses for turbo codes by reducing the degradation associated with a sliding window MAP decoder based turbo decoder, and therefore increases the usefulness of turbo codes.

### BRIEF DESCRIPTION OF THE INVENTION

A method and apparatus for improving the performance of decoder that uses a sliding window decoder is described. In accordance with one embodiment of the invention, receive samples are decoded by first processing continuously in a first direction and using overlapping windows in a second direction, and then by decoded continuously in the second direction and using overlapping windows in the first direction. Typically, the decodings correspond to subiterations in a decoding iteration of a turbo code or other iterative code. The entire decoding process typically involves multiple decoding iterations and therefore has particular application to turbo codes and as well as other codes designed for iterative decoding.

### DETAILED DESCRIPTION OF THE INVENTION

A method and apparatus for reducing degradation from a sliding window decoder is described. In the following description the invention is set forth with reference to various timing diagrams and block diagrams, The events and blocks represent steps that are performed in a method-step process, an apparatus for performing each step, or a combination thereof. Preferably, the apparatus are implemented using electronic devices such as semiconductor based integrated circuits or discrete components that control current or voltage signals using techniques that are well known in the art.

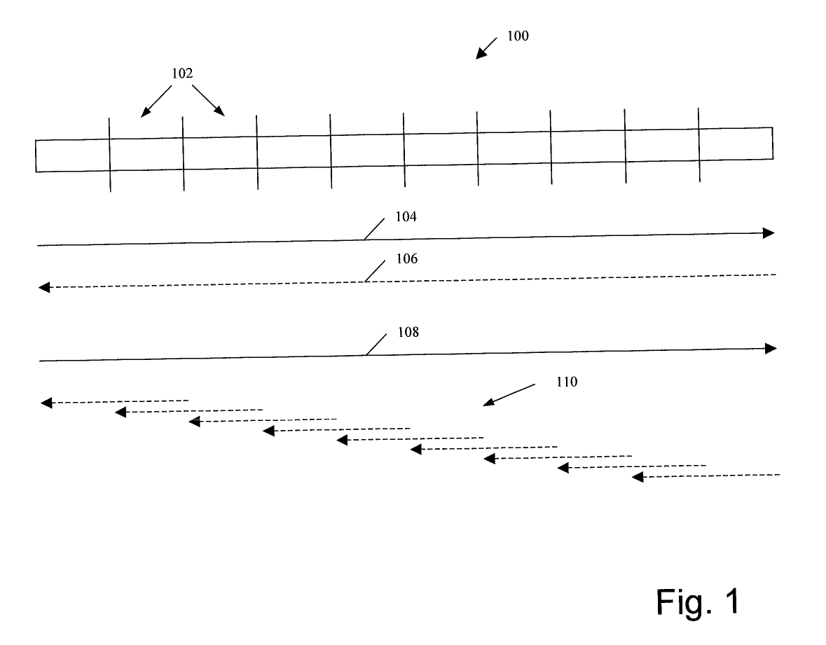

FIG. 1 is a diagram illustrating the processing of a frame (packet) of data using fully continuous MAP decoding and sliding window decoding. It should be noted that true MAP (multiplication based) or log-MAP (addition based) decoding may be used. Frame 100 represents a frame of encoded receive samples that have typically been transmitted through a noisy channel. Frame 100 is divided into sections (referred to as “windows”) 102.

The fully continuous block MAP decoding process involves several subdecoding steps. In an exemplary decoding, a forward direction subdecoding 104 is performed first over an entire block of data. Often the block corresponds to a terminated frame of data that has been encoded. During forward direction subdecoding 104 a set of state metrics (forward state metrics) for each sample are stored. The forward direction subdecoding is followed by a reverse direction subdecoding 106. During the reverse direction subdecoding 106 the resulting reverse state metrics are combined with the stored forward state metrics in a generalized dual maxima computation to generate soft decisions and extrinsic information. The order of the forward and reverse direction subdecoding can be reversed, with the reverse state metrics being stored instead of the forward state metrics.

When the first subdecoding is performance over the entire frame before the second, opposite direction subdecoding is performed, this is referred to a fully continuous MAP decoding process. While performing a fully continuous MAP decoding process provides the most accurate decoding results (the fewest number of errors), for large frames storing all the forward state metrics requires too much memory for practical or cost effective implementation on an integrated circuit. To reduce the amount of memory necessary to perform MAP decoding a sliding window decoding architecture can be employed.

In an exemplary sliding window decoding process, one of the subdecodings is performed in a series of overlapping windows 110. For example, as the forward direction subdecoding is performed windows of forward state metrics are stored and then combined with windows of reverse state metrics to yielding soft decision and extrinsic information. Once a window of forward and reverse state metrics have been processed, the state metrics from both subdecodings can be discarded releasing the memory for the processing of the next window. In some implementations, two sets of reverse metrics are generated simultaneously to increase decoding speed.

Discarding the state metrics after each window of the frame has been processed reduces the memory requirements for decoding substantially. This memory reduction facilitates cost effective implementation of a MAP decoder on an integrated circuit, which in turn facilitates implementation of MAP decoder based turbo codes. However, the use of the sliding widow MAP decoders does degrade the accuracy of the decoding processing, leaving greater numbers of uncorrected errors (when compared to fully continuous MAP decoding) once the decoding process has been completed.

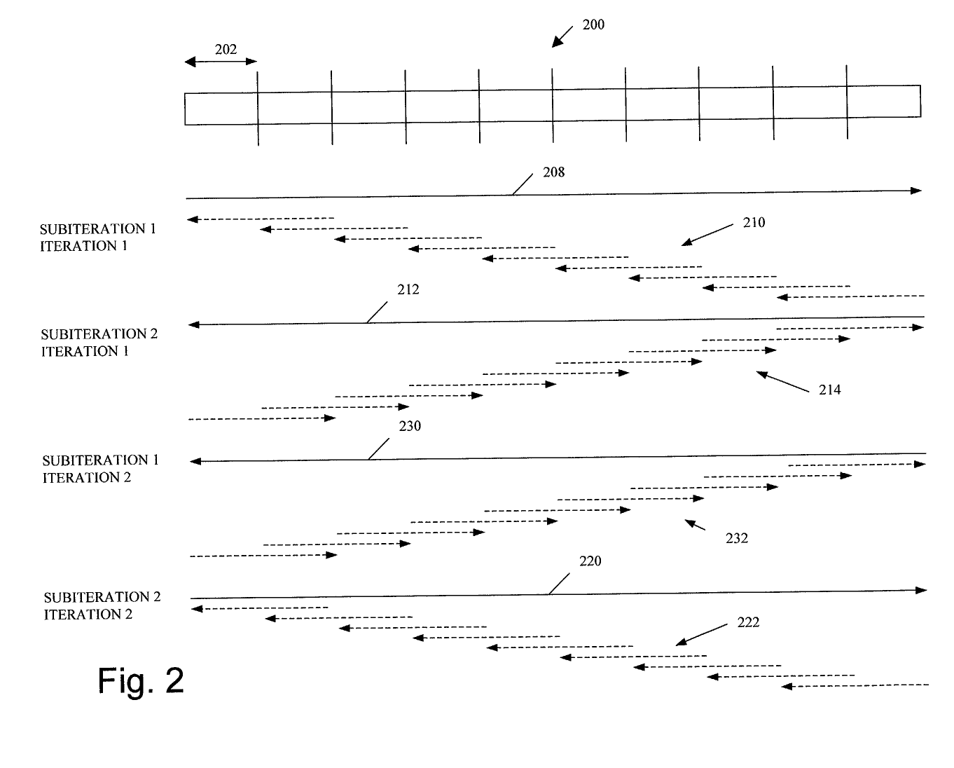

FIG. 2 is a timing diagram illustrating the decoding of a frame when performed in accordance with one embodiment of the invention. The frame of receive samples 200 are divided into windows 202.

The exemplary decoding is performed using a turbo code comprised of two constituent codes. While the use two constituent codes is common in the art, the use of more than two codes is consistent with the use of the invention. Additionally, the invention can be practiced with the constituent codes placed in various turbo code configurations including parallel, serial or hybrid configurations. A description of a serial concatenated turbo code is in “Serial Concatenation of Interleaved Codes: Performance Analysis, Design, and Iterative Decoding,” S. Benedetto, D. Divsalar, G. Montorsi, F. Pollara, TDA Progress Report 42-126, Aug. 15, 1996, incorporated herein by reference.

During decoding, a first iteration is conducted by performing a set of subiterations, with each subiteration corresponding to a constituent code within the turbo code. A first subiteration is performed by decoding continuously 208 in the forward direction 208 and by decoding in overlapping sliding windows 210 in the reverse direction. As described above, the use of the overlapping sliding window when decoding in one direction facilitates practical implementation on a semiconductor device.

The second subiteration is then performed by decoding continuously 212 in the reverse direction and by decoding in overlapping windows 214 in the forward direction. As should be apparent, the continuously decoded direction for the second subiteration is switched with respect to the continuously decoded direction for the first subiteration.

A second iteration is then conducted by performing the (new) first subiteration by decoding continuously 230 in the reverse direction and using overlapping windows 232 in the forward direction. The second subiteration of the second iteration is then performed by decoding continuously 220 in the forward direction, and decoding using overlapping windows 222 in the reverse direction.

As should be apparent, the direction for which continuous decoding is performed over the multiple decoding steps (subiterations) is switched during the processing of the frame. In the described embodiment, the direction is switched between each subiteration in a particular iteration, and between corresponding subiterations in different iterations. For a two constituent code turbo code, this causes the direction in which continuous decoding is performed to switch for each subiteration.

Switching the direction in which continuos decoding is performed as the frame is processed reduces the number of error remaining after decoding, and therefore reduces the degradation introduced by use of a sliding window MAP decoding process. This reduction in degradation is performed with minimal impact on the resources necessary to perform decoding because each particular decoding step (subiteration) is still performed using a sliding window process. Thus, the implementation benefits of using a sliding window process are maintained while the corresponding reduction in performance (degradation) is reduced.

The above-described embodiment of the invention switches the continuous and overlapping window direction each subiteration. While tests have shown this pattern provides excellent results in terms of increase in performance for a minimal increase in implementation complexity, there are other embodiments of the invention that still provide error rate reductions.

For example, in a first alternative embodiment the direction in which continues decoding is performed may be switched only from iteration to iteration. That is, all the subiterations for a particular iteration are performed continuously in one direction, but the continuous direction is switched between different iterations. This embodiment reduces the complexity of implementation, but does not provide the performance improvements of switching each subiteration.

Other embodiments of the invention may provide other alternative patterns for switching the direction of continuous decoding. In general, any switching of direction of continues decoding between decoding steps (subiterations) will provide performance improvements. However, embodiments where the direction switching is performed between each consecutive subiteration in an iteration, and where direction switching is performed for the same subiteration (and therefore constituent code) over different iterations, or both, provide the greatest level of improvement for minimal additional complexity and speed reduction.

Alternative embodiments of the invention may also choose to reduce the size of the overlapping sliding window in order to increase speed and further reduce memory requirements for a given level of performance.

In still another embodiment of the invention, additional performance improvements are obtained with a minimal increase in complexity, but with some loss of processing speed. In this embodiment of the invention a particular subiteration is performed twice within the same iteration. One subiteration is performed with the continuous decoding in a first direction and one decoding is performed with the continuous decoding in the second direction. As would be expected, this embodiment increasing the total number of subdecoding and decoding steps, and therefore the total time required to process a frame is increased. However, memory requirements are still kept low, and therefore where sufficient signal processing resources and device speed are available, this embodiment could be preferred.

FIG. 2A illustrates still another embodiment of the invention. While FIG. 2 shows the continuous decoding as being conducted in continuous fashion across the entire frame, FIG. 2A illustrates that the continuous decoding steps may also be subdivided into longer subsections (258, 262, 270 and 280) that are decoded in overlapping fashion. In this case, the processing of the frame is divided into “longer windows” and “shorter” windows, rather than continuous and overlapping windows. The short windows correspond to the overlapping windows, while the longer windows correspond to the continuous direction. Typically the longer windows are more than four times longer then the shorter windows, however, the important aspect is that, for a particular subiteration, one processing in one direction be more “continuous” than processing in the other.

In general, where the term “continuous” is used (including in the disclosure and the claims) both continuous and longer overlapping windows may be used. For example, as shown in FIG. 2A, the shorter and longer overlapping subsection directions are switched between different subiterations and iterations, rather fully continues and overlapping window processing.

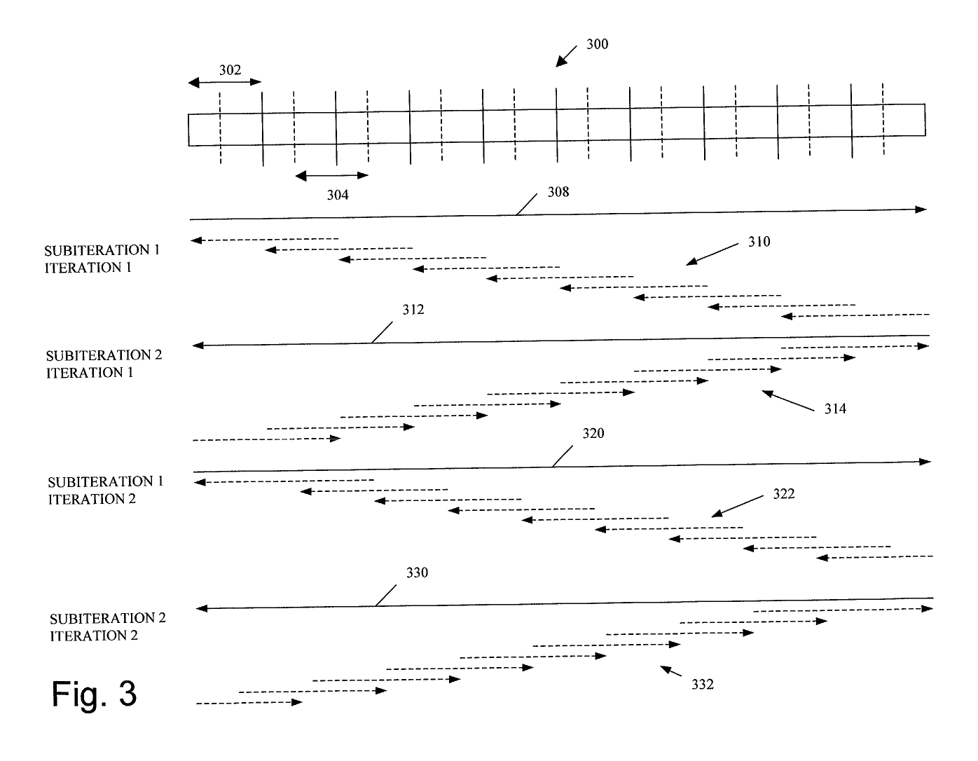

FIG. 3 is a timing diagram illustrating an alternative embodiment of the invention. Frame 300 is divided into windows 302 and offset windows 304. During the first iteration the first subiteration is performed by decoding continuously in the forward direction and by decoding in overlapping sliding windows in the reverse direction. In the exemplary embodiment, the overlapping windows for the first iteration correspond to the first set of sliding windows 302.

During the second subiteration the decoding is performed continuously in reverse direction and using overlapping windows in the forward direction. As should be apparent the continuous direction and overlapping window direction are reversed with respect to the first subiteration. Additionally, for the second subiteration the overlapping sliding windows correspond to sliding windows 304, which are offset with respect to windows 302. Preferably, windows 304 are offset by 50% with respect to windows 302. As illustrated the first overlapping sliding window processing step 314 is longer that the remaining sliding window processing steps 314, due to the offset nature of windows 304. Alternatively, the first sliding window could be shorter than the other overlapping sliding windows.

During the first subiteration of the second iteration, the frame is processed by decoding continuously 320 in the reverse direction and using overlapping windows 322 in the forward direction. During this subiteration the overlapping windows are formed using offset windows 304. In contrast, the first subiteration performed during the first iteration uses windows 302. Thus, the continuous decoding and overlapping window directions are switched with respect to the first subiteration performed during the first iteration. Additionally, the windows are switched from windows 302 to offset windows 304.

Similarly, the second subiteration of the second iteration is performed by decoding continuously 330 in the forward direction and by using overlapping windows 332 in the reverse direction. In the described embodiment, the overlapping windows during this subiteration are formed according to windows 302. Thus, the direction of continuous and sliding window decoding are switched with respect to the second subiteration of the first iteration, as are the window offsets used for the sliding window decoding.

By switching the window offset used for sliding window decoding, this embodiment of the invention improves decoding performance by further reducing the degradation introduced by use of a sliding window decoding process and architecture. While switching the window offset typically requires additional control circuitry with respect to some other embodiments of the invention, the amount of additional complexity is generally manageable. Memory requirements remain basically the same, and a device incorporated this embodiment of the invention can be readily realized on an integrated circuit. Thus, most the implementation benefits of a sliding window decoder are realized without the same level of degradation in performance.

Alternative embodiments of the invention may just incorporate the use of different window offsets without changing the direction of the continuous and sliding window subdecodings, although best performance is realized when these processes are combined. Also, while the embodiment described with respect to FIG. 3 switches the window offset for each subiteration, other embodiments of the invention may switch the offset in differing patterns. Also longer and shorter windows may be employed as described with respect to FIG. 2A.

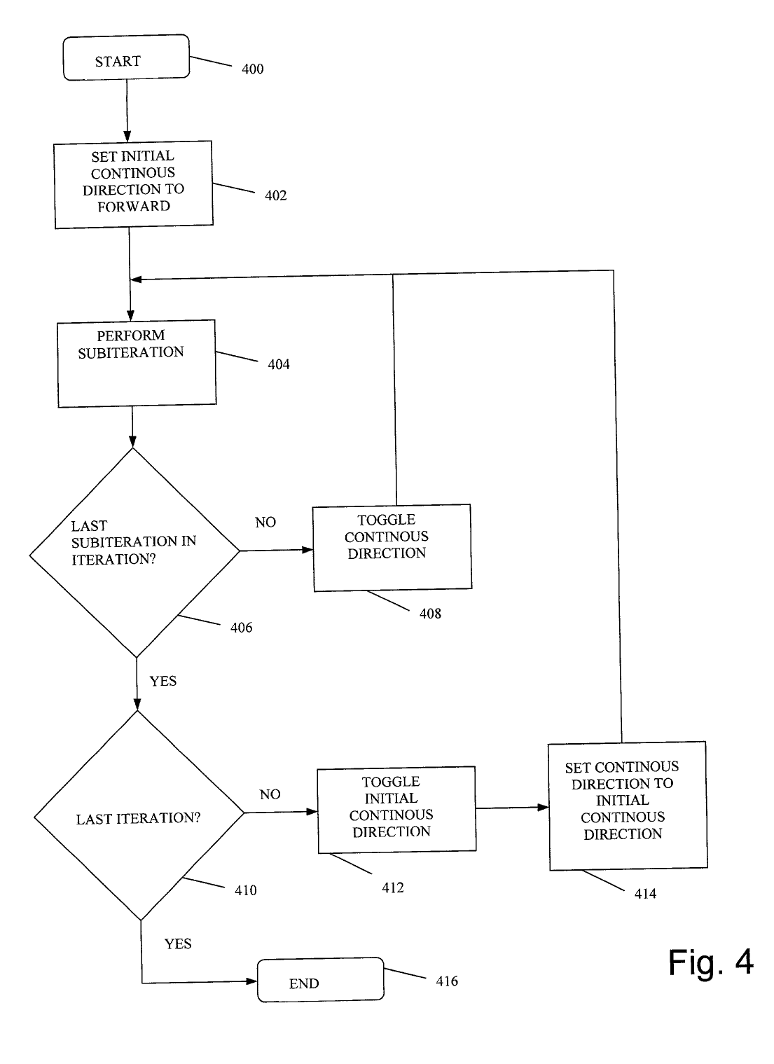

FIG. 4 is a flow chart illustrating an exemplary decoding performed in accordance with one embodiment of the invention. Decoding begins at step 400 and at step 402 the continuous decoding direction is set to forward. Additionally, the sliding window decoding (subdecoding) direction is set to reverse. At step 404 the first subiteration is performed based on the current continuous and sliding widow directions. In this case, the continuous direction is forward and the sliding window direction is reverse.

At step 406 it is determined if the last subiteration for the iteration has been performed, and if not the continuous and sliding window directions are toggled at step 408 and the next subiteration is performed at step 404. During this subiteration, decoding is performed continuously in the reverse direction and using sliding windows in the forward direction.

If at step 406 it is determined that the last subiteration for the iteration has been performed, and therefore that the iteration has been completed, it is determined at step 410 whether the last iteration has been completed and the frame has been decoded. If so, the decoding of the frame ends at step 416.

If that last iteration has not been performed, the initial continuous and sliding window decoding directions are toggled at step 412. That is the continuous and sliding window decoding directions are toggle with respect to settings used at the start of the previous iteration. For the second iteration, this corresponds to the opposite of the initialization values used in step 402. Once the directions have been set in step 412 the next subiteration is performed at step 404.

By decoding a frame in accordance with the embodiment of the invention described in FIG. 4 the continuously decoding direction will switch for each subiteration in an iteration. Additionally, the continuously decoding and sliding window decoding directions for a particular subiteration are also switched between any two consecutive iterations. While other patterns of direction switching are consistent with some embodiment of the invention, simulations have shown switching as shown in FIG. 4 to provide excellent performance improvements with minimal additional complexity. Additionally, performing decoding as shown in FIG. 4 provides excellent performance with codes with different numbers of constituent codes. For example, the process shown in FIG. 4 can be used with codes having two constituent codes, three constituent codes, or more than three constituent codes.

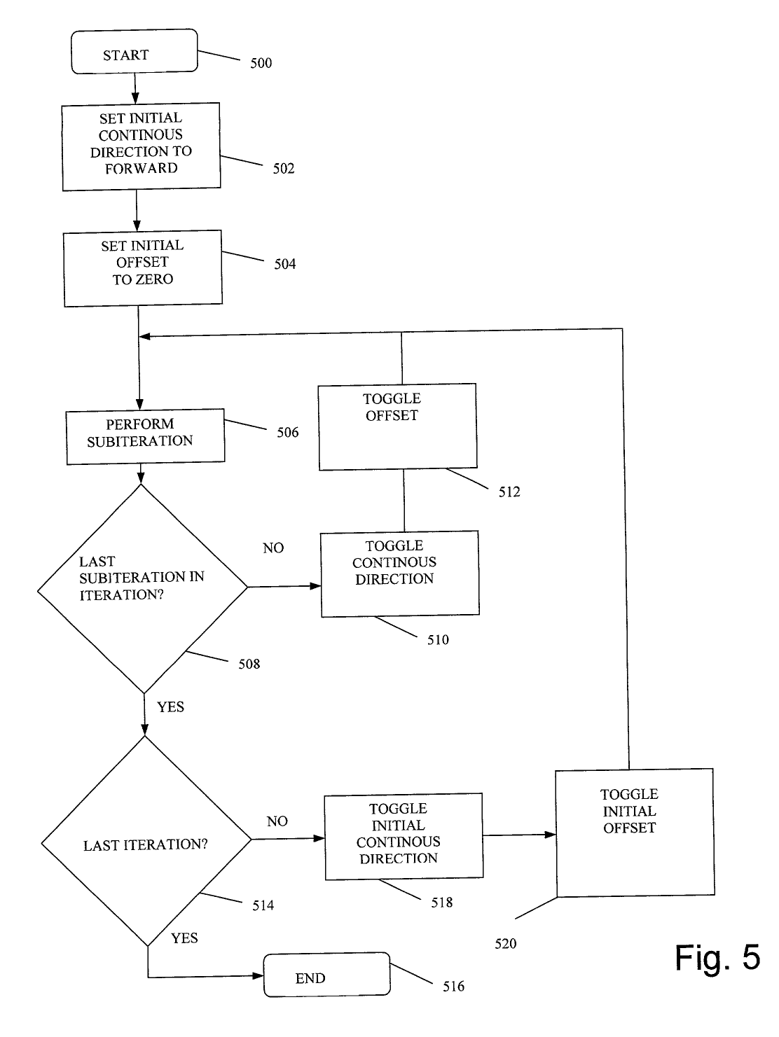

FIG. 5 is a flow chart illustrating an exemplary decoding performed in accordance with one embodiment of the invention. Decoding begins at step 500 and at step 502 the continuous decoding direction is set to forward. Additionally, the sliding window direction is set to reverse. At step 504 the frame offset is set to a first frame offset of zero. At step 506 the first subiteration is performed based on the current continuous and sliding widow directions as well as the current offset. In this case, the continuous direction is forward, the sliding window direction is reverse and the offset is zero.

At step 508 it is determined if the last subiteration for the iteration has been performed, and if not the continuous and sliding window directions are toggled at step 510 and the offset is toggled at step 512. As described above typically two possible offsets are used where one offset causes a window to start in the middle of the windows created using the other offset.

The next subiteration is then performed at step 506. During this subiteration, decoding is performed continuously in the reverse direction, using sliding windows in the forward direction, and with the second offset.

If at step 508 it is determined that the last subiteration for the current iteration has been performed, and therefore that the iteration has been completed, it is determined at step 514 whether the last iteration has been completed and therefore if the frame has been decoded. If so, the decoding of the frame ends at step 516.

If that last iteration has not been performed, the initial continuous decoding direction sliding window decoding direction are toggled at step 512. That is, the continuous and sliding window decoding directions are toggled with respect to settings used at the start of the previous iteration. Additionally, the initial offset is toggled between the first and second offset at step 514. For the second iteration, this corresponds to the opposite of the initialization values used in steps 502 and 504. Once the directions and offset have been set, the next subiteration is performed at step 506.

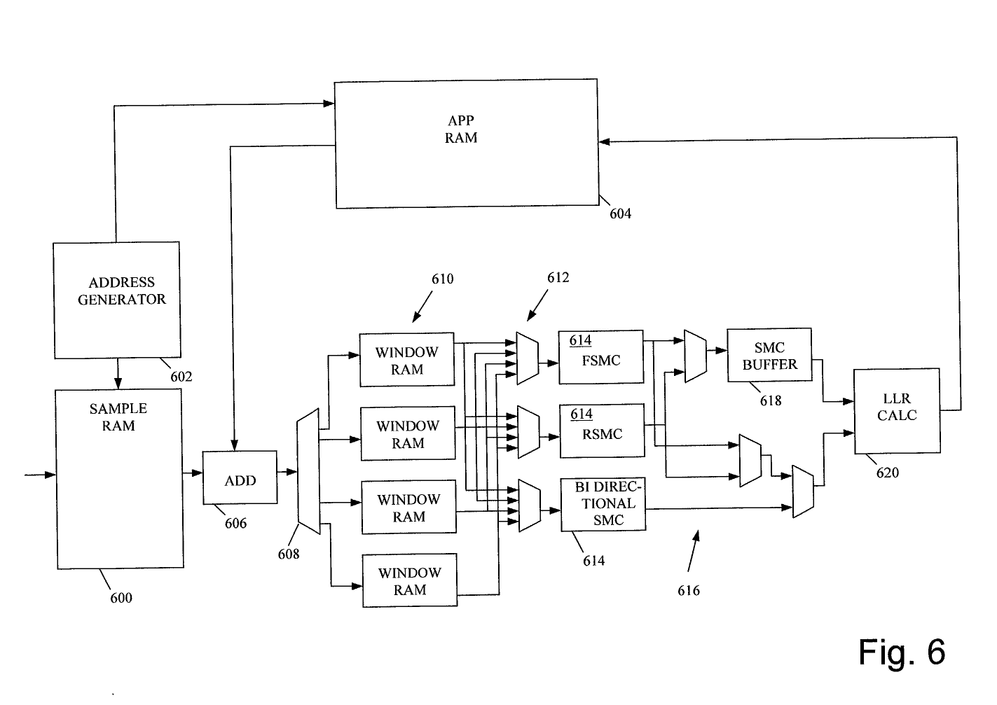

FIG. 6 is a block diagram of a decoder configured in accordance with one embodiment of the invention. Sample RAM 600 is coupled to add circuit 606 and address generator 602. Mux 608 is coupled to add circuit 606 and window rams 610. Multiplexors 612 are coupled to window rams 610 and state metric calculators (SMC) 614. Multiplexors 616 are coupled between state metric calculators 614 and SMC buffer 618 as well as log-likelihood ratio (LLR) calculator 620. Apriori (APP) RAM 604 is coupled to LLR calculator 620 and address generator 602.

During operation, receive samples are stored within sample RAM 600. Address generator 602 reads out the samples from sample RAM and the APP values form APP RAM 604 according to a predetermined pseudo-random interleaver pattern. Add circuit 606 adds the APP values to the systematic samples stored within sample RAM 600 and the resulting adjusted samples are written to one of the window rams 610.

In accordance with one embodiment of the invention, the psuedo random interleaver is an s-type (spread) interleaver. It is based on the random generation of N integers from 0 to N−1 constrained to spread out the addresses. In particular, each randomly selected integer is compared to the S most recently selected integers. If the current selection is within S of at least one of the previous S integers, then it is rejected and a new integer is selected until the previous condition is satisfied.

While the use of s-type interleavers provides excellent performance, this types of interleaver requires the use of look-up tables operations to generate. Other interleavers that require look-up tables include dithered golden interleavers as described in Performance of Turbo-Codes with Relative Prime and Golden Interleaving Strategies, S. Crozier, J. Lodge, P. Guinand, and A Hunt, Communications Research Center, 3701 Carling Ave., PO Box 11490, Station H, Ottawa, Canada.

Multiple interleavers may also be used in code with more than two constituent codes.

The values stored within the remaining window rams 610 (i.e. the window rams not being written to) are applied to state metric calculators 614. In the described embodiment state metric calculators are comprised of a forward state metric calculator (FSMC) that processes the frame in the forward direction, a reverse state metric calculator (RSMC) that processes the frame in the reverse direction and a bi-directional state metric calculator that can be configured to process the frame in both the forward and reverse direction. In the preferred embodiment of the invention, each state metric calculator also includes a branch metric calculation unit.

When the frame is being processed, for example, continuously in the forward direction and using sliding windows in the reverse direction, bi-directional SMC 614 is configured to process the frame in the reverse direction. RSMC 614 and bi-directional SCM 614 simultaneously process the overlapping windows and the resulting reverse state metrics are alternating applied to LLR calculator 620. SMC buffer 618 receives the forward state metrics from FSMC 614 and, after each half window of samples are processed applies, those forward state metrics to LLR calculator. Similarly, the reverse state metrics are applied in alternating fashion by muxes 616 to LLR calculator 620, where the source alternates each half window. The resulting LLR values are stored within APP memory 604 to be used during the next subiteration.

When the frame is being processed continuously in the reverse direction and using sliding windows in the forward direction, bi-directional SMC 614 is configured to process the frame in the forward direction. FSMC 614 and bi-directional SCM 614 simultaneously process the overlapping windows and the resulting forward state metrics are alternating applied to LLR calculator 620. SMC buffer 618 receives the reverse state metrics from RSMC 614 and, after each half window of samples are processed, those reverse state metrics are applied to LLR calculator 620. Similarly, the forward state metrics are applied in alternating fashion by muxes 616 to LLR calculator 620, where the source alternates each half window. The resulting LLR values are stored within APP memory 604 to be used during the next subiteration.

The implementation of branch metric calculators, state metric calculators, MAP decoders and log-MAP decoders is well known. An example of a paper describing such an implementation is Implementation and Performance of a Turbo/MAP Decoder, Steven S. Pietrobon, Submitted to the International Journal of Satellite Communications 21 February 1997.

By providing a configurable bi-directional state metric calculator along with a forward and reverse state metric calculator the described embodiment allows frames to be decoding using a sliding window process were the sliding window direction can be easily shifted between different iterations and subiterations. Performing sliding window decoding where the direction of the sliding window and continuous decoding is changed during the decoding process provided improved decoding performance including a lower error rate. The above described decoder provides these improvements with a minimum of additional hardware.

Other embodiments of the invention may be done as follows:

A method for iteratively decoding an encoded frame of received samples, the encoded frame being encoded using a first constituent encoder and a second constituent encode, said method comprising the steps of:

a) decoding, according to said first constituent encoder, said encoded frame in longer overlapping windows in a first direction and using shorter overlapping windows in said second direction;

b) decoding said encoded frame, according to said second constituent encoded, in longer overlapping windows in said second direction and using shorter overlapping windows in said first direction.

A method of transmitting data over a channel comprising the steps of:

a) encoding said data using a first constituent encoder and a second constituent encoder;

b) transmitting said data over said channel;

c) decoding said data by performing a plurality of first constituent decoder based decoding steps, said plurality of first constituent decoder based decoding steps including a first subset of decoding steps performed using longer windows in a first direction and shorter windows in a second direction, and by performing a plurality of second constituent decoder based decoding steps, said plurality of second constituent decoder based decoding steps including a third subset of decoding steps performed using longer windows in a first direction and shorter windows in a second direction, and by performing a plurality of second constituent decoder based decoding steps.

A method for decoding a data encoded using a first constituent encoder and a second constituent encoder comprising the steps of:

a) performing a plurality of first constituent decoder based decoding steps, said plurality of first constituent decoder based decoding steps including a first subset of decoding steps performed using longer windows in a first direction and shorter windows in a second direction;

b) performing a plurality of second constituent decoder based decoding steps, said plurality of second constituent decoder based decoding steps including a third subset of decoding steps performed using longer windows in a first direction and shorter windows in a second direction, and by performing a plurality of second constituent decoder based decoding steps.

A method for decoding a data encoded using a first constituent encoder and a second constituent encoder comprising the steps of:

a) performing a plurality of first constituent decoder based decoding steps, said plurality of first constituent decoder based decoding steps including a first subset of decoding steps performed continuously in a first direction and shorter windows in a second direction;

b) performing a plurality of second constituent decoder based decoding steps, said plurality of second constituent decoder based decoding steps including a third subset of decoding steps performed continuously in a first direction and shorter windows in a second direction, and by performing a plurality of second constituent decoder based decoding steps.

A decoder for decoding a frame of receive samples comprising:

first bi-directional state metric calculator from generating forward state metrics by processing the frame in the forward direction and for generating reverse state metrics by processing the frame in the reverse direction;

second bi-directional state metric calculator from generating forward state metrics by processing the frame in the forward direction and for generating reverse state metrics by processing the frame in the reverse direction;

control unit for configuring said first bi-directional state metric calculator to process the frame is sliding windows in the forward direction and said second state metric calculator to processes said frame continuously in the reverse direction during a first subiteration, and for configuring said second bi-directional state metric calculator to process the frame is sliding windows in the reverse direction and said first bi-directional state metric calculator to processes said frame continuously in the forward direction during a second subiteration

A decoder for decoding a frame of receive samples comprising:

forward state metric calculator for generating forward state metrics by processing the frame in the forward direction;

reverse state metric calculator for generating reverse state metrics by processing the frame in the reverse direction;

bi-directional state metric calculator from generating forward state metrics by processing the frame in the forward direction and for generating reverse state metrics by processing the frame in the reverse direction;

control unit for configuring said bi-directional state metric calculator and said forward state metric calculator to process the frame is sliding windows in the forward direction and said reverse state metric calculator to processes said frame continuously in the reverse direction during a first subiteration, and for configuring said bi-directional state metric calculator and said reverse state metric calculator to process the frame is sliding windows in the reverse direction and said forward state metric calculator to processes said frame continuously in the forward direction during a second subiteration.

a) decoding said frame using longer windows in a first direction and using shorter overlapping windows in a second direction;

b) decoding said frame using shorter overlapping windows in said second direction and using longer windows in said first direction.

A method for iteratively decoding an encoded frame of receive samples, the encoded frame being encoded using a first constituent encoder and a second constituent encode, said method comprising the steps of:

a) performing a first set of decodings according to said first constituent encoder, said first set of decodings being performed continuously over more than window length in a first direction and using overlapping windows in a second direction;

b) performing a second set of decodings according to said first constituent encoder, said second set of decodings being performed continuously over more than window length in said second direction and using overlapping windows in said first direction.

Thus, a method and apparatus for reducing degradation from a sliding window decoder is described. The previous description was provided for purposed of illustration only, and those skilled in the art will recognize various alternative embodiments of the invention, the scope of which is set forth in the following claims:

1. A method for iteratively decoding a frame of receive samples comprising the steps of:
a) decoding said frame continuously in a first direction and using overlapping windows in a second direction;
b) decoding said frame continuously in said second direction and using overlapping windows in said first direction.

2. A method for iteratively decoding an encoded frame of received samples, the encoded frame being encoded using a first constituent encoder and a second constituent encode, said method comprising the steps of:
a) decoding, according to said first constituent encoder, said encoded frame continuously in a first direction and using overlapping windows in said second direction;
b) decoding said encoded frame, according to said second constituent encoded, continuously in said second direction and using overlapping windows in said first direction.

3. The method as set forth in claim 2 further comprising the steps of
c) decoding, according to said first constituent encoder, said encoded frame continuously in said second direction and using overlapping windows in said first direction;
d) decoding said encoded frame, according to said second constituent encoded, continuously in said first direction and using overlapping windows in said second direction.

4. A method for iteratively decoding an encoded frame of receive samples, the encoded frame being encoded using a first constituent encoder and a second constituent encode, said method comprising the steps of:
a) performing a first iteration by decoding, according to said first constituent encoder, said encoded frame continuously in a first direction and using overlapping windows in said second direction, and decoding said encoded frame, according to said second constituent encoded, continuously in said first direction and using overlapping windows in said second direction;
b) performing a second iteration by decoding, according to said first constituent encoder, said encoded frame continuously in said second direction and using overlapping windows in said first direction, decoding said encoded frame, according to said second constituent encoded, continuously in said second direction and using overlapping windows in said first direction.

5. A decoder for decoding a frame of receive samples comprising:
sliding window decoding means for performing sliding window decoding in a first direction and a second direction;
continuous decoding means for performing continuous decoding in said first direction and said second direction;
control mean for configuring said sliding window decoding means to decode in said first direction and said continuous decoding means to decode in said second direction during a first subiteration, and configuring said sliding window decoding means to decode in said second direction and said continuous decoding means to decode in said first direction during a second subiteration.

6. A decoder for decoding a frame of receive samples comprising:
first sliding window decoder for performing sliding window decoding in a first direction;
second sliding window decoder for performing sliding window decoding in a second direction;
first continuous decoder for performing continuous decoding in said first direction;
second continuous decoder for performing continuous decoding in said second direction;
control means for configuring said first sliding window decoding means to decode the frame and said second continuous decoding means to decode the frame during a first subiteration, and configuring said second sliding window decoding means to decode the frame and said first continuous decoding means to decode the frame during a second subiteration.
